(19) United States
(12) Patent Application Publication
(10) Pub. No.: US 2026/0068701 A1
(43) Pub. Date: Mar. 5, 2026

(54) INTERPOSER DEVICES HAVING MULTIPLE SETS OF COMPONENTS FORMED THEREON

(71) Applicant: Applied Materials, Inc., Santa Clara, CA (US)

(72) Inventors: Shivkumar Chiruvolu, San Jose, CA (US); Ameet S. Bhansali, Pleasanton, CA (US); Steven Verhaverbeke, San Francisco, CA (US)

(21) Appl. No.: 19/302,298

(22) Filed: Aug. 18, 2025

Related U.S. Application Data
(63) Continuation-in-part of application No. 19/224,986, filed on Jun. 2, 2025.
(60) Provisional application No. 63/687,731, filed on Aug. 27, 2024.

(51) Int. Cl. H01L 23/538; H01L 23/14; H01L 25/18; H10B 80/00; H10D 80/30

(52) U.S. Cl. CPC H01L 23/5383; H10B 80/00; H10D 80/30

(57) ABSTRACT

An interposer device includes a first core, a second core hybrid bonded to the first core, a first redistribution layer (RDL), and a second RDL. The first core and the second core are located between the first RDL and the second RDL.

### CROSS-REFERENCE TO RELATED APPLICATION(S)

The present application is a continuation-in-part of U.S. patent application Ser. No. 19/224,986, filed on Jun. 2, 2025 and entitled “CORE SUBSTRATES WITH EMBEDDED COMPONENTS”, which claims priority to U.S. Provisional Patent Application No. 63/687,731, filed on Aug. 27, 2024 and entitled “High-bandwidth memory Via Embedding and Stacking of Memory Into Silicon Core,” the entire contents of each of which are hereby incorporated by reference herein.

### TECHNICAL FIELD

Embodiments of the present disclosure relate to interposers, and more particularly to interposer devices multiple sets of components formed thereon. In particular, one set of components can be formed on a first side of an interposer device, and another set of components can be formed on a second side of the interposer device opposite the first side.

### BACKGROUND

A co-packaged device (e.g., multi-chip module) can include multiple components assembled together. One example of a component is a processor component (e.g., processor chip). For example, a processor component can include one or more of a graphics processing unit (GPU), a central processing unit (CPU), a data processing unit (DPU), a neural processing unit (NPU), an extensible processing unit (XPU), an application-specific integrated circuit (ASIC), etc. Another example of a component is a memory component (e.g., memory chip). For example, a memory component can be a high-bandwidth memory (HBM) component. HBM is a type of computer memory that is designed to provide high bandwidth at lower power consumption, primarily for high-performance computing (HPC) applications. Examples of high-performance computing applications include high-resolution graphics rendering (e.g., using GPU(s)), artificial intelligence (AI), data analytics, and/or machine learning (ML).

### SUMMARY

In some embodiments, an interposer device includes a first core, a second core hybrid bonded to the first core, a first redistribution layer (RDL), and a second RDL. The first core and the second core are located between the first RDL and the second RDL.

In some embodiments, a system includes an interposer device, a first set of components formed on a first side of the interposer device, and a second set of components formed on second side of the interposer device opposite the first side. The interposer device includes a first core, a second core hybrid bonded to the first core, a first redistribution layer (RDL), and a second RDL. The first core and the second core are located between the first RDL and the second RDL.

In some embodiments, a system includes an interposer device, a high-bandwidth memory (HBM) device formed on a first side of the interposer device, and a second HBM device formed on a second side of the interposer device opposite the first side. The interposer device includes a first core and a second core hybrid bonded to the first core. The first core includes a first redistribution layer including a first dielectric layer, a first through-substrate via (TSV) connected to the first redistribution layer, and a first core substrate embedded within the first dielectric layer. The second core includes a second redistribution layer including a second dielectric layer, a second TSV connected to the second redistribution layer, and a second core substrate embedded within the second dielectric layer. The first TSV extends through the first core substrate and the second TSV extends through the second core substrate.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a block diagram of an example system including a substrate core with embedded components, according to some embodiments.

FIGS. 2A-2B are diagrams of example systems including core substrates with embedded active components, according to some embodiments.

FIG. 3A is a diagram of an example system including a core substrate with embedded passive components, according to some embodiments.

FIGS. 3B-3D are diagrams of example passive components that can be embedded within a core substrate, according to some embodiments.

FIG. 4 is a flowchart of an example method of fabricating a system including a device with one or more embedded components, according to some embodiments.

FIG. 5 is a diagram of a system including a substrate having hybrid bonded core substrates, according to some embodiments.

### DETAILED DESCRIPTION

A co-packaged device can be fabricated using 2.5 dimension (2.5D) packaging, which is viewed as a bridge between typical two-dimensional (2D) packaging in which components are mounted side by side on a substrate, and full three-dimensional (3D) packaging in which components are stacked vertically (e.g., multiple components are vertically stacked and interconnected by through substrate vias (TSVs)). To implement 2.5D packaging, multiple components can be disposed on an interposer device (also referred to as an interposer) or a chip-to-chip interconnect device. An interposer is an electrical interface that routes connections between the components. For example, an interposer can function as a high-density interconnect platform between the components, and can provide shorter connections and larger bandwidth as compared to typical printed circuit board (PCB) or substrate-based connections. For example, each component can be embodied as a chiplet, which is a function-specific device. The modular design of 2.5D packaging can provide benefits as compared to traditional 2D packaging techniques, such as improved yield and design customization. Accordingly, 2.5D packaging can enable the combination of different types of components (processor components, memory components, etc.) into a single package, in contrast to combining the functionality of each component into a single monolithic component (e.g., single chip).

Access to a large capacity memory has improved with the introduction of HBM components. However, some multi-die or multi-chiplet computing systems (e.g., those fabricated using 2.5D packaging) can be memory deficient. Such memory deficiency can be a bottleneck for HPC systems, such as multi-die computing systems with accelerators. For example, some HBM stacks fabricated using 2.5D packaging can utilize short connections through a bridge or interposer to be connected to a processor component for latency and energy efficiency.

One potential way to address these and other drawbacks of multi-die or multi-chiplet computing systems is by vertically stacking components (e.g., processor components and/or memory components) using 3D packaging techniques. However, vertical stacking of components may not be possible with typical core substrates, or with redistribution layer (RDL) interposers and silicon-bridge options.

Embodiments of the present disclosure relate to core substrates (e.g., for interposers or chip-to-chip interconnects) with embedded components. Embodiments described herein can provide for an interposer device that enables both the mounting of components on at least one side of the device, referred to herein as “non-embedded components,” and the embedding of one or more components within a core substrate of the device, referred to herein as “embedded components.”

The non-embedded components formed on at least one side of the device can include a combination of processor components and memory components. In some embodiments, the non-embedded components include alternating processor components and memory components, in which a processor component is mounted adjacent to a memory component (and vice versa). A processor component can include one or more processing units. Examples of processing units include CPUs, GPUs, DPUs, NPUs, XPUs, ASICs, etc. In some embodiments, a memory component is an HBM component.

The embedded components can be formed within a core substrate. In some embodiments, the core substrate is a silicon (Si) substrate. The core substrate can be made in very large sizes (e.g., up to 210 millimeters (mm)×210 mm), and can have a coefficient of thermal expansion (CTE) that is matched with the CTE of the non-embedded components and the embedded components. A device described herein can be well suited for true 3D stacking of non-embedded components and embedding of embedding components.

In some embodiments, the one or more embedded components include at least one an active component. For example, an active component can be a memory component. In some embodiments, a memory component is an HBM component. As another example, an active component can be a processor component including one or more processing units. Examples of processing units include CPUs, GPUs, DPUs, NPUs, XPUs, ASICs, etc. Illustratively, if the embedded components include memory components (e.g., HBM components), then the embedded memory components can enable larger banks of memory as compared to traditional interposer devices.

In some embodiments, the one or more embedded components include at least one passive component. Examples of passive components include capacitors (e.g., trench capacitors), transistors (e.g., gallium nitride (GaN) transistors), switches (e.g., GaN switches), resistors (e.g., thin film resistors), inductors (e.g., magnetic core thin film inductors), liquid cooling channels, etc.

Embodiments described herein provide for various technical advantages. For example, providing capability for embedding components within a core substrate and mounting components on at least one side of the core substrate can increase the number of processing and/or memory resources. Accordingly, embodiments described herein can be used to enhance capacity and/or bandwidth of co-packaged devices that include interposers, and can reduce the bottleneck of shoreline resource (e.g., memory resource) availability associated with 2.5D packaged systems.

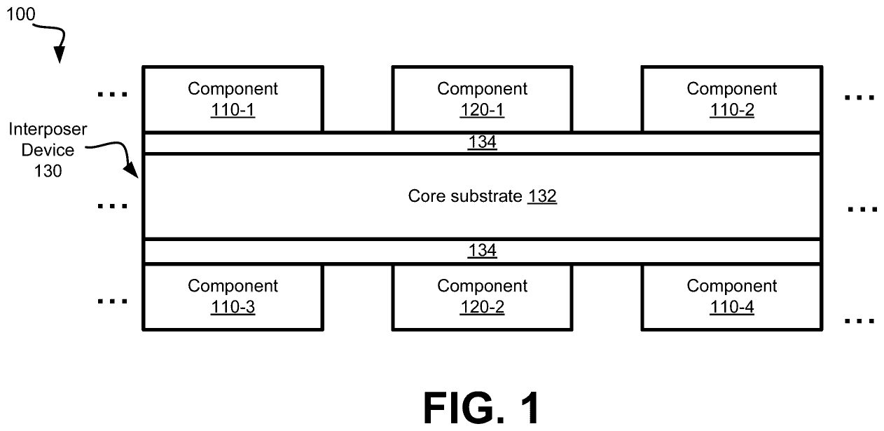

FIG. 1 is a block diagram of an example system 100, according to some embodiments. As shown in FIG. 1, the system 100 can include non-embedded components 110-1, 110-2 and 120-1 formed on a first side of a device 130, and non-embedded components 110-3, 110-4 and 120-2 formed on a second side of device 130 opposite the first side. In some embodiments, device 130 is an interposer device. In some embodiments, device 130 is a substrate that may be used to interconnect components without use of an interposer, such as a chip-to-chip interconnect. In some embodiments, the non-embedded components 110-1 through 110-4 are memory components and the non-embedded components 120-1 and 120-2 are processor components. In some embodiments, the non-embedded components 110-1 through 110-4 are processor components and the non-embedded components 120-1 and 120-2 are memory components. In some embodiments, at least one memory component is an HBM component. In some embodiments, at least one processor component includes at least one of a GPU, a CPU, a DPU, an NPU, an XPU, an ASIC etc.

As shown, the device 130 can include a core substrate 132. The core substrate 132 can have any suitable thickness. In some embodiments, the thickness of the core substrate 132 is less than or equal to about 770 μm.

In some embodiments, RDLs 134 are formed on both sides of the core substrate 132. The RDLs 134 can include interconnect structures (e.g., conductive lines and vias). Each interconnect structure (e.g., via and conductive line) can be formed from any suitable conductive material. Examples of suitable conductive materials include copper (Cu), tungsten (W), aluminum (Al), silver (Ag), gold (Au), molybdenum (Mo), titanium (Ti), tantalum (Ta), etc. The RDLs 134 can include high-density wiring (e.g., having an about 2 μm line/space (L/S) ratio). Such RDLs 134 can be well-suited for longer across-the-substrate distance signal and power.

One or more embedded components can be formed within the core substrate 132 (not shown in FIG. 1). The core substrate 132 can be made in large sizes (e.g., up to about 210 mm long by about 210 mm wide), and can have a CTE that is matched with the CTE of the embedded components. In some embodiments, the core substrate 132 is a Si substrate. However, the core substrate 132 can include any suitable material (e.g., glass, organic material, laminate material).

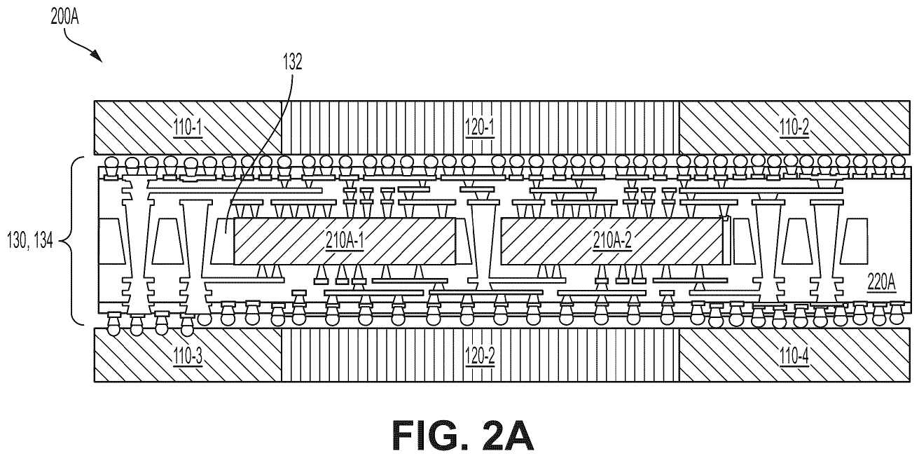

In some embodiments, the one or more embedded components include at least one active component. For example, an active component can be a memory component. In some embodiments, a memory component is an HBM component. As another example, an active component can be a processor component including one or more processing units. Examples of processing units include CPUs, GPUs, DPUs, NPUs, XPUs, ASICs, etc. Illustratively, if the embedded components include memory components (e.g., HBM components), then the embedded memory components can enable larger banks of memory as compared to traditional interposer devices. Examples of core substrates 132 including embedded active components will be described below with reference to FIGS. 2A-2B.

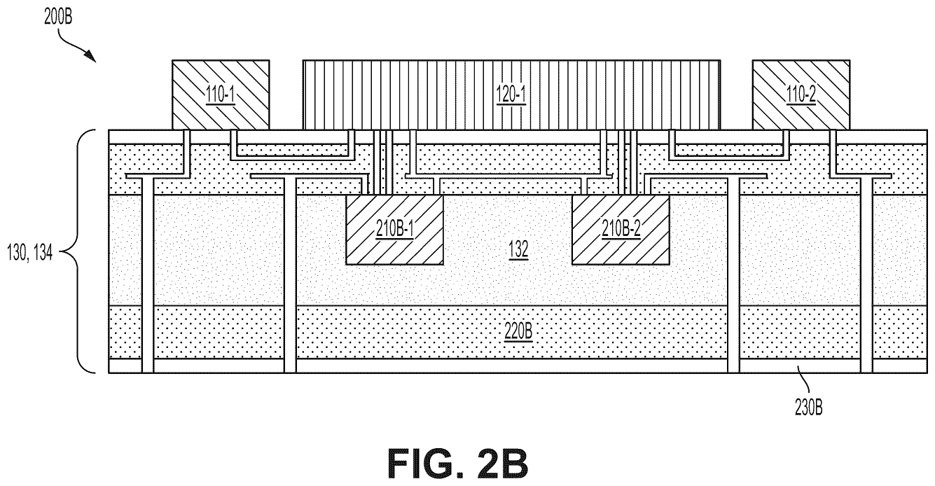

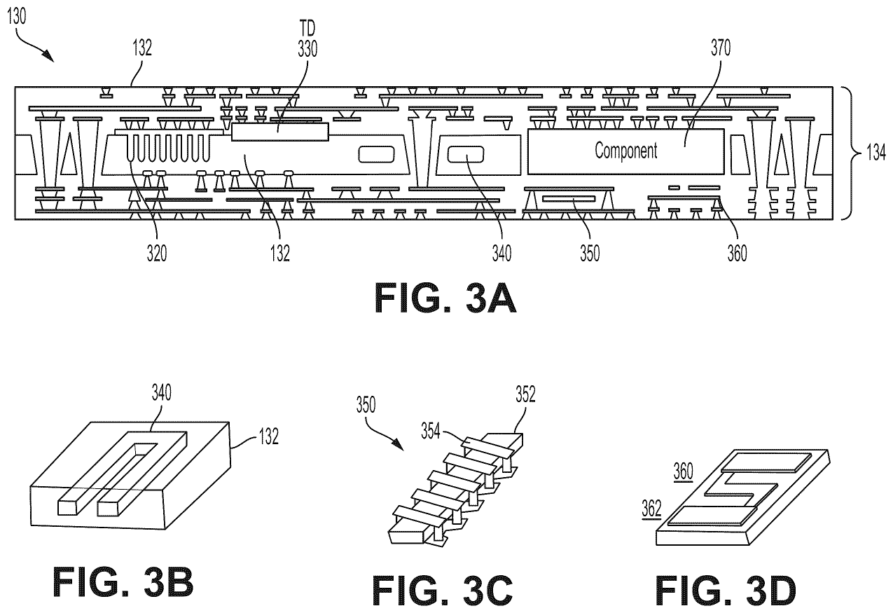

In some embodiments, the one or more embedded components include at least one passive component. Examples of passive components include capacitors (e.g., trench capacitors), transistors (e.g., GaN transistors), switches (e.g., GaN switches), resistors (e.g., thin film resistors), inductors (e.g., magnetic core thin film inductors), liquid cooling channels, etc. Examples of core substrates 132 including embedded passive components will be described below with reference to FIGS. 3A-3D.

FIG. 2A is a block diagram of an example system 200A, according to some embodiments. In some embodiments, the system 200A includes a multichip module for HPC applications.

For example, the system 200A can include the non-embedded components 110-1 through 110-4, 120-1 and 120-2, and the device 130 including the core substrate 132 and the RDLs 134 described above with reference to FIG. 1. In some embodiments, the non-embedded components include alternating processor components and memory components, in which a processor component is mounted adjacent to a memory component (and vice versa). For example, components 110-1 through 110-4 can be memory components and components 120-1 and 120-2 can be processor components. However, such embodiments should not be considered limiting.

As further shown, the system 200A includes embedded components 210A-1 and 210A-2. In some embodiments, the embedded components 210A-1 and 210A-2 are active components. For example, at least one of the embedded components 210A-1 or 210A-2 can be a processor component. As another example, at least one of the embedded components 210A-1 or 210A-2 can be a memory component. As further shown, the RDLs 134 can be formed within an RDL substrate 220A. In some embodiments, the RDL substrate 220A includes an organic material (e.g., organic RDL buildup). In some embodiments, the RDL substrate 220A includes an inorganic material (e.g., inorganic RDL buildup).

FIG. 2B is a block diagram of an example system 200B, according to some embodiments. In some embodiments, the system 200B includes multichip module for HPC applications. For example, the system 200A can include the non-embedded components 110-1, 110-2 and 120-1, and the device 130 including the core substrate 132 and the RDLs 134 described above with reference to FIG. 1. In some embodiments, the non-embedded components include alternating processor components and memory components, in which a processor component is mounted adjacent to a memory component (and vice versa). For example, components 110-1 and 110-2 can be memory components and components 120-1 can be a processor component. However, such embodiments should not be considered limiting.

As further shown, the system 200B can include embedded components 210B-1 and 210B-2. In some embodiments, the embedded components 210B-1 and 210B-2 are active components. For example, at least one of the embedded components 210B-4 or 210B-2 can be a processor component. As another example, at least one of the embedded components 210B-1 or 210B-2 can be a memory component. As further shown, the RDLs 134 can be formed within an RDL substrate 220B. In some embodiments, the RDL substrate 220B includes an organic material (e.g., organic RDL buildup). In some embodiments, the RDL substrate 220B includes an inorganic material (e.g., inorganic RDL buildup). As further shown, the system 200B can include bottom layer 230B.

FIG. 3A is a cross-sectional view of an example device 130, according to some embodiments. The device 130 can include the core substrate 132 and the RDLs 134 including interconnect structures (e.g., conductive lines and vias) as described above with reference to FIGS. 1-2B.

The device 130 can include embedded passive components. For example, the embedded passive components of the device 130 can include a trench capacitor 320 formed within the core substrate 132. Unlike traditional capacitors which are flat, trench capacitors are 3D and formed by etching deep trenches into a substrate (e.g., the core substrate 132). This 3D structure of trench capacitors allows for higher capacitance per unit area compared to traditional capacitors.

The embedded passive components of the device 130 can further include a transistor device (TD) 330 formed within the core substrate 132. In some embodiments, the TD 330 is a GaN transistor device.

The embedded passive components of the device 130 can further include liquid cooling channels 340 embedded within the core substrate 132. FIG. 3B is a diagram illustrating a perspective view of the liquid cooling channels 340, according to some embodiments.

The embedded passive components of the device 130 can further include an inductor 350. In some embodiments, the inductor 350 is a magnetic core inductor. For example, the inductor 350 can be a magnetic core thin film inductor. FIG. 3C is a diagram illustrating a perspective view of the inductor 350, and particularly a magnetic core inductor (e.g., magnetic core thin film inductor). For example, the inductor 350 can include a magnetic core 352, and a conductive material 354 formed around the magnetic core 352. The magnetic core 352 can include any suitable material. In some embodiments, the magnetic core 352 includes cadmium zinc telluride (CZT). The conductive material 354 can include any suitable material. In some embodiments, the conductive material 354 includes Cu.

The embedded passive components of the device 130 can further include a resistor 360. In some embodiments, the resistor 360 is a thin film resistor. FIG. 3D is a diagram illustrating a perspective view of the resistor 360 (e.g., thin film resistor). For example, the resistor 360 can include a film 362, and a conductive material 364. The film 362 can include any suitable material. In some embodiments, the film 362 includes metal nitride (example tantalum nitride (TaN)) and the resistor 360 is a TaN resistor or a nichrome (NiCr) resister. The conductive material 364 can include any suitable material. In some embodiments, the conductive material 364 includes Cu.

The device 130 can further include at least one embedded active component 370 (e.g., processor component and/or memory component).

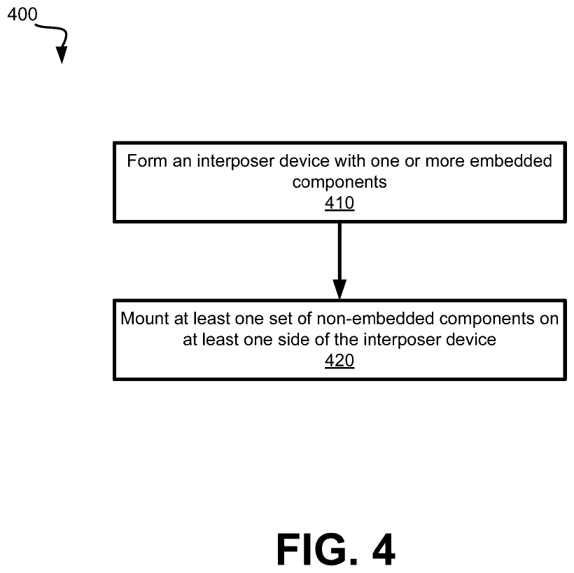

FIG. 4 is a flowchart of an example method 400 of fabricating a system including a device (e.g., an interposer device) with one or more embedded components, according to some embodiments.

At block 410, a device with one or more embedded components is formed. More specifically, forming the device can include embedding the one or more embedded components within a core substrate. In some embodiments, the core substrate is a Si substrate. Forming the device can further include forming RDLs. More specifically, the RDLs can include interconnect structures formed within an RDL substrate. In some embodiments, the RDL substrate includes an organic material. In some embodiments, the RDL substrate includes an inorganic material.

In some embodiments, the one or more embedded components include at least one an active component. For example, an active component can be a memory component. In some embodiments, a memory component is an HBM component. As another example, an active component can be a processor component including one or more processing units. Examples of processing units include CPUs, GPUs, DPUs, NPUs, XPUs, ASICs, etc. Illustratively, if the embedded components include memory components (e.g., HBM components), then the embedded memory components can enable larger banks of memory as compared to traditional interposer devices.

In some embodiments, the one or more embedded components include at least one a passive component. Examples of passive components include capacitors (e.g., trench capacitors), transistors (e.g., GaN transistors), switches (e.g., GaN switches), resistors (e.g., thin film resistors), inductors (e.g., magnetic core thin film inductors), liquid cooling channels, etc.

At block 420, at least one set of non-embedded components is formed on at least one side of the device. In some embodiments, the one or more non-embedded components include at least one an active component. For example, an active component can be a memory component. In some embodiments, a memory component is an HBM component. As another example, an active component can be a processor component including one or more processing units. Examples of processing units include CPUs, GPUs, DPUs, NPUs, XPUs, ASICs, etc.

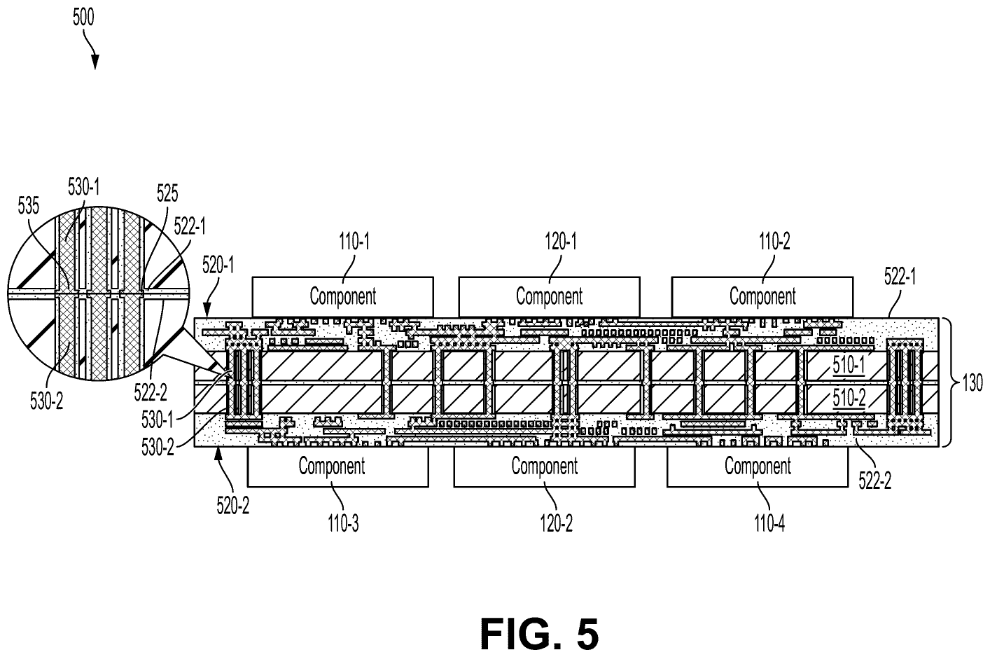

FIG. 5 is a diagram of a system 500 including the non-embedded components 110-1 through 110-4, 120-1 and 120-2 formed on the device 130 of FIG. 1, according to some embodiments. The non-embedded components 110-1 through 110-4, 120-1 and 120-2 may correspond to any of the aforementioned components. In some embodiments, the non-embedded components 110-1 through 110-4 are memory components (e.g., HBM components) and the non-embedded components 120-1 and 120-2 are processor components (e.g., CPUs, GPUs, DPUs, NPUs, XPUs, ASICs, etc.).

In this illustrative example, the device 130 can include multiple core substrates, such as core substrate 510-1 and core substrate 510-2. In some embodiments, the core substrates are Si core substrates.

The device 130 can further include multiple RDLs, such as RDL 520-1 and RDL 520-1. The RDLs may include respective dielectric layers. For example, the RDL 520-1 can include a dielectric layer 522-1 and the RDL 520-1 can include a dielectric layer 522-2. In some embodiments, each of the dielectric layer 522-1 and the dielectric layer 522-2 includes an inorganic dielectric material.

The RDLs can further include interconnect structures for electrical routing (e.g., vias, pads, etc.) therein. The interconnect structures may be formed of a conductive material such as a metal (e.g., copper) in some embodiments. For example, the RDL 520-1 can include a TSV 530-1 formed through the core substrate 510-1 and the RDL 520-2 can include a TSV 530-2 formed through the core substrate 510-2.

The dielectric layer 522-1 can be bonded to the dielectric layer 522-2, as indicated by bond 525 (e.g., dielectric bond), and the TSV 530-1 can be aligned and bonded to the TSV 530-2, as indicated by bond 535 (e.g., metal bond). In particular, the bond 525 and the bond 535 can be formed via hybrid bonding. In some embodiments, the dielectric layer is a bond 525 that bonds the two core substrates. Accordingly, the TSV 530-1 and TSV 530-2 can collectively form a single TSV that extends through the core substrate 510-1 and the core substrate 510-2.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In some embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method can be altered so that certain operations can be performed in an inverse order or so that certain operation can be performed, at least in part, concurrently with other operations. In another embodiment, instructions or sub-operations of distinct operations can be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. An interposer device comprising:
a first core;
a second core hybrid bonded to the first core;
a first redistribution layer (RDL) layer; and
a second RDL;
wherein the first core and the second core are located between the first RDL and the second RDL.

2. The interposer device of claim 1, further comprising a first through-substrate via (TSV) connected to the first RDL and a second TSV connected to the second RDL, wherein, to hybrid bond the first core to the second core, the first TSV is bonded to the second TSV.

3. The interposer device of claim 1, wherein the first core comprises a first core substrate embedded within the first dielectric layer, wherein the second core comprise a second core substrate embedded within a second dielectric layer, and wherein, to hybrid bond the first core to the second core, the first dielectric layer is bonded to the second dielectric layer.

4. The interposer device of claim 3, wherein the first dielectric layer and the second dielectric layer each comprise an inorganic dielectric material.

5. The interposer device of claim 3, wherein the first core substrate and the second core substrate are each a silicon core substrate.

6. A system comprising:
an interposer device;
a first set of components formed on a first side of the interposer device; and
a second set of components formed on second side of the interposer device opposite the first side;
wherein the interposer device comprises:
a first core;
a second core hybrid bonded to the first core;
a first redistribution layer (RDL) layer; and
a second RDL;
wherein the first core and the second core are located between the first RDL and the second RDL.

7. The system of claim 6, further comprising a first through-substrate via (TSV) connected to the first RDL and a second TSV connected to the second RDL, wherein, to hybrid bond the first core to the second core, the first TSV is bonded to the second TSV.

8. The system of claim 6, wherein the first core comprises a first core substrate embedded within the first dielectric layer, wherein the second core comprise a second core substrate embedded within a second dielectric layer, and wherein, to hybrid bond the first core to the second core, the first dielectric layer is bonded to the second dielectric layer.

9. The system of claim 8, wherein the first dielectric layer and the second dielectric layer each comprise an inorganic dielectric material.

10. The system of claim 8, wherein the first core substrate and the second core substrate are each a silicon core substrate.

11. The system of claim 6, wherein the first set of components comprises a first memory component, and wherein the second set of components comprises a second memory component.

12. The system of claim 11, wherein the first memory component and the second memory component are each a high-bandwidth memory (HBM) component.

13. The system of claim 6, wherein the first set of components comprises a first processor component comprising one or more first processing units, and wherein the second set of components comprises a second processor component comprising one or more second processing units.

14. The system of claim 13, wherein the one or more first processing units comprise at least one of: one or more central processing units (CPUs), one or more graphics processing units (GPUs), one or more data processing units (DPUs), one or more neural processing units (NPUs), one or more extensible processing units (XPUs), or one or more application-specific integrated circuits (ASICs).

15. A system comprising:
an interposer device;
a first high-bandwidth memory (HBM) component formed on a first side of the interposer device; and
a second HBM component formed on second side of the interposer device opposite the first side;
wherein the interposer device comprises:
a first core comprising:
a first redistribution layer comprising a first dielectric layer;
a first through-substrate via (TSV) connected to the first redistribution layer; and
a first core substrate embedded within the first dielectric layer, wherein the first TSV extends through the first core substrate; and
a second core hybrid bonded to the first core, the second core comprising;
a second redistribution layer comprising a second dielectric layer;
a second TSV connected to the first redistribution layer; and
a second core substrate embedded within the second dielectric layer,
wherein the second TSV extends through the second core substrate.

16. The system of claim 15, further comprising a first processor component formed on the first side and a second processor component formed on the second side.

17. The system of claim 16, wherein the first process component comprises at least one of: one or more central processing units (CPUs), one or more graphics processing units (GPUs), one or more data processing units (DPUs), one or more neural processing units (NPUs), one or more extensible processing units (XPUs), or one or more application-specific integrated circuits (ASICs).

18. The system of claim 15, wherein the first dielectric layer and the second dielectric layer each comprise an inorganic dielectric material.

19. The system of claim 15, wherein the first core substrate and the second core substrate are each a silicon core substrate.
